(19) United States
(12) Patent Application Publication
(10) Pub. No.: US 2025/0149437 A1
(43) Pub. Date: May 8, 2025

(54) INTERCONNECTION STRUCTURE

(71) Applicant: TAIWAN SEMICONDUCTOR MANUFACTURING COMPANY, LTD., Hsinchu (TW)

(72) Inventors: Wei-Chen CHU, Hsinchu (TW); Chia-Chen LEE, Hsinchu (TW); Chia-Tien WU, Hsinchu (TW)

(73) Assignee: TAIWAN SEMICONDUCTOR MANUFACTURING COMPANY, LTD., Hsinchu (TW)

(21) Appl. No.: 18/502,792

(22) Filed: Nov. 6, 2023

(51) Int. Cl. H01L 23/522; H01L 21/768; H01L 23/528

(52) U.S. Cl. CPC H01L 23/5226; H01L 21/76816; H01L 23/5283

(57) ABSTRACT

An interconnection structure includes a semiconductor substrate that is formed with a first metal trench and a second metal trench, a first metal via, a second metal via, a third metal trench and a fourth metal trench. The first metal via is disposed over and connected to the first metal trench. The second metal via is disposed over and connected to the second metal trench. The third metal trench is disposed over and connected to the first metal via. The fourth metal trench that is disposed over and connected to the second metal via. A thickness of the third metal trench is different from a thickness of the fourth metal trench.

### BACKGROUND

The semiconductor integrated circuit (IC) industry has over the past decades experienced tremendous advancements and is still experiencing vigorous development. However, advances in IC design need to be accompanied by improvements in manufacturing in order to optimize device performance. As an example, interconnections between different layers of wires and associated dielectrics affect IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a sectional view illustrating an interconnection structure in accordance with a first embodiment.

FIG. 2 is a sectional view illustrating an interconnection structure in accordance with a second embodiment.

FIG. 3 is a sectional view illustrating an interconnection structure in accordance with a third embodiment.

FIG. 4 is a flow chart illustrating steps of a method for fabricating an interconnection structure in accordance with the second embodiment.

FIGS. 5 through 10 are sectional views illustrating intermediate stages of the method for fabricating the interconnection structure in accordance with the second embodiment.

FIG. 11 is a flow chart illustrating steps of a method for fabricating an interconnection structure in accordance with the third embodiment.

FIGS. 12 through 15 are sectional views illustrating intermediate stages of the method for fabricating the interconnection structure in accordance with the third embodiment.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly,” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions.

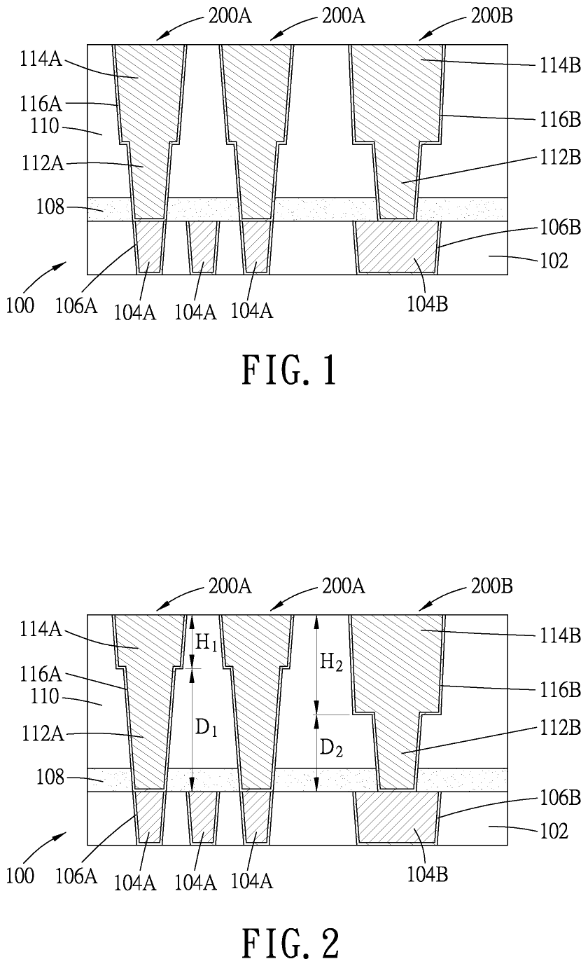

FIG. 1 illustrates a sectional view of an interconnection structure that is formed over a substrate 100 in accordance with a first embodiment. The substrate 100 may be a bulk semiconductor substrate or a semiconductor-on-insulator (SOI) substrate, which may be doped (e.g., with a p-type or an n-type dopant) or undoped. In some embodiments, an SOI substrate includes a layer of a semiconductor material formed on an insulator layer. The insulator layer may be a buried oxide (BOX) layer, a silicon oxide layer or any other suitable layer. The insulator layer may be provided on a suitable substrate, such as silicon, glass or the like. The substrate 100 may be made of a suitable semiconductor material, such as silicon or the like. In some embodiments, the substrate 100 is a silicon substrate; and in other embodiments, the substrate 100 is made of a compound semiconductor such as silicon carbide, gallium arsenide, indium arsenide, indium phosphide or other suitable materials. In still other embodiments, the substrate 100 is made of an alloy semiconductor such as GaAsP, AlInAs, AlGaAs, GalnAs, GalnP, GaInAsP or other suitable materials.

In some embodiments, the substrate 100 includes various p-type doped regions and/or n-type doped regions, such as p-type wells, n-type wells, p-type source/drain features and/or n-type source/drain features (source/drain feature(s) may refer to a source or a drain, individually or collectively depending upon the context), formed by a suitable process such as ion implantation, thermal diffusion, a combination thereof, or the like. In some embodiments, the substrate 100 may include other functional elements such as resistors, capacitors, diodes, transistors, and/or the like. The transistors are, for example, field effect transistors (FETs), such as planar FETs and/or 3D FETs (e.g., FinFETs, GAAFETs). The substrate 100 may include lateral isolation features (e.g., shallow trench isolation (STI)) configured to separate various functional elements formed on the substrate 100 and/or various functional elements formed in the substrate 100.

In this embodiment, the substrate 100 includes a first interconnection layer formed on top. The first interconnection layer includes a first dielectric 102, one or more metal trenches 104A formed in the first dielectric 102, and one or more metal trenches 104B formed in the first dielectric 102. In the illustrative embodiment, the metal trench or trenches 104A are made for use in a capacitance-sensitive region; and the metal trench or trenches 104B are made for use in a resistance-sensitive region and thus are made wider than the metal trench or trenches 104A. The capacitance-sensitive region refers to a circuit region that has short signal paths and/or high densities of metal lines, such as a logic circuit region, a peripheral circuit region, etc., while the resistance-sensitive region refers to a circuit region that has long signal paths and/or large pitches among metal lines, such as a circuit region of memory bit lines. In the illustrative embodiment, the substrate 100 is exemplified to include multiple metal trenches 104A and one metal trench 104B for ease of explanation, but this disclosure is not limited in this respect. Between each metal trench 104A and the first dielectric 102, a barrier film 106A is conformally disposed on a sidewall of the metal trench 104A to prevent metal atoms in the metal trench 104A from diffusing into the first dielectric 102. Similarly, between the metal trench 104B and the first dielectric 102, a barrier film 106B is conformally disposed on a sidewall of the metal trench 104B to prevent metal atoms in the metal trench 104B from diffusing into the first dielectric 102. In accordance with some embodiments, the first dielectric 102 may contain elements of, for example, Si, O, C, N, H, other suitable elements, or any combination thereof. In accordance with some embodiments, the first dielectric 102 may include, for example, silicon oxide, silicon nitride, silicon carbide, low-k materials, other suitable materials, or any combination thereof. In accordance with some embodiments, the first dielectric 102 may have a thickness in a range from about 200 angstroms to about 2000 angstroms, but this disclosure is not limited in this respect. In accordance with some embodiments, the metal trenches 104A, 104B may include, for example, Cu, Ru, W, Ti, Al, Co, Mo, Ir, Rh, Ta, other suitable materials, or any combination thereof. In accordance with some embodiments, the metal trenches 104A, 104B may have a thickness in a range from about 100 angstroms to about 1000 angstroms. In accordance with some embodiments, the barrier films 116A and 116B are different from the metal trenches 104A, 104B in terms of materials, and may include, for example, Ru, W, Ti, Al, Co, Mo, Ir, Rh, Ta, any nitride of these metals, other suitable materials, or any combination thereof. In accordance with some embodiments, the barrier films 106A and 106B may be omitted depending on the bulk metal used in the metal trenches 104A, 104B, and this disclosure is not limited in this respect.

The interconnection structure includes a second interconnection layer formed over the first interconnection layer. The second interconnection layer includes a second dielectric 110 disposed over the substrate 100 with an etch stop layer 108 formed between the first dielectric 102 and the second dielectric 110, and multiple interconnection features 200A, 200B formed in the second dielectric 110. The etch stop layer 108 may have either a single-layer structure or a multilayer structure, and contain elements of, for example, Si, O, C, N, H, Al, Zr, other suitable elements, or any combination thereof. In accordance with some embodiments, the etch stop layer 108 may include, for example, silicon oxide, silicon nitride, silicon carbide, aluminum oxide, aluminum nitride, aluminum carbide, zirconium oxide, zirconium nitride, zirconium oxide, silicon carbon nitride, oxygen doped silicon carbide, other suitable materials, or any combination thereof. In accordance with some embodiments, the etch stop layer 108 may have a thickness in a range from about 5 angstroms to about 200 angstroms, but this disclosure is not limited in this respect. Each interconnection feature 200A is disposed in the capacitance-sensitive region, and includes a metal trench 114A, and a metal via 112A that interconnects the metal trench 114A and a corresponding one of the metal trenches 104A. The metal via 112A is disposed over and connected to the corresponding metal trench 104A, extends from the corresponding metal trench 104A to the metal trench 114A vertically relative to a top surface of the substrate 100, and penetrates the etch stop layer 108. The metal trench 114A is disposed over and connected to the corresponding metal via 112A, and extends parallel to the top surface of the substrate 100. The interconnection feature 200B is disposed in the resistance-sensitive region, and includes a metal trench 114B, and a metal via 112B that interconnects the metal trench 114B and the metal trench 104B. The metal via 112B is disposed over and connected to the metal trench 104B, extends from the metal trench 104B to the metal trench 114B vertically relative to the top surface of the substrate 100, and penetrates the etch stop layer 108. The metal trench 114B is disposed over and connected to the metal via 112B, and extends parallel to the top surface of the substrate 100. Since the metal trench 114B is disposed in the resistance-sensitive region, the metal trench 114B may be made wider than the metal trenches 114A to achieve a smaller resistance. In the illustrative embodiment, each interconnection feature 200A further includes a barrier film 116A that is conformally disposed on sidewalls of the metal via 112A and the metal trench 114A; and the interconnection feature 200B further includes a barrier film 116B that is conformally disposed on sidewalls of the metal via 112B and the metal trench 114B. In detail, the barrier film 116A is interposed between the metal via 112A and the second dielectric 110 and between the metal trench 114A and the second dielectric 110 to prevent metal atoms in the metal via 112A and the metal trench 114A from diffusing into the second dielectric 110; and the barrier film 116B is interposed between the metal via 112B and the second dielectric 110 and between the metal trench 114B and the second dielectric 110 to prevent metal atoms in the metal via 112B and the metal trench 114B from diffusing into the second dielectric 110. In accordance with some embodiments, the second dielectric 110 may contain elements of, for example, Si, O, C, N, H, other suitable elements, or any combination thereof. In accordance with some embodiments, the second dielectric 110 may include, for example, silicon oxide, silicon nitride, silicon carbide, low-k materials, other suitable materials, or any combination thereof. In accordance with some embodiments, the second dielectric 110 may have a thickness in a range from about 200 angstroms to about 2000 angstroms, but this disclosure is not limited in this respect. In accordance with some embodiments, the metal vias 112A, 112B and the metal trenches 114A, 114B may include, for example, Cu, Ru, W, Ti, Al, Co, Mo, Ir, Rh, Ta, other suitable materials, or any combination thereof. In accordance with some embodiments, each of the metal vias 112A, 112B and the metal trenches 114A, 114B may have a thickness in a range from about 100 angstroms to about 1000 angstroms. In accordance with some embodiments, the barrier films 116A and 116B are different from the metal vias 112A, 112B and the metal trenches 114A, 114B in terms of materials, and may include, for example, Ru, W, Ti, Al, Co, Mo, Ir, Rh, Ta, any nitride of these metals, other suitable materials, or any combination thereof. In accordance with some embodiments, the barrier films 116A and 116B may be omitted depending on the bulk metal used in the metal vias 112A, 112B and the metal trenches 114A, 114B, and this disclosure is not limited in this respect. In the first embodiment, the metal vias 112A, 112B and the metal trenches 114A, 114B may be formed using a dual damascene process, so the metal via 112A and the metal trench 114A of each interconnection feature 200A are formed in one piece, and the metal via 112B and the metal trench 114B of the interconnection feature 200B are formed in one piece. The metal vias 112A, 112B have substantially the same thickness, and the metal trenches 114A, 114B have substantially the same thickness. In more detail, the metal trenches 114A, 114B have coplanar top surfaces and coplanar bottom surfaces, and so do the metal vias 112A, 112B.

FIG. 2 illustrates a sectional view of an interconnection structure in accordance with a second embodiment, where the interconnection structure is fabricated using a modified dual damascene process. The second embodiment is similar to the first embodiment, and differs from the first embodiment in that, in the second embodiment, a thickness H1 of the metal trenches 114A is different from a thickness H2 of the metal trench 114B. In other words, a distance between a top surface and a bottom surface of a single metal trench 114A is different from a distance between a top surface and a bottom surface of the metal trench 114B. To be specific, the thickness H1 of the metal trenches 114A that are formed in the capacitance-sensitive region is smaller than the thickness H2 of the metal trench 114B that is formed in the resistance-sensitive region, so the metal trenches 114A may induce less trench-to-trench capacitance therebetween in the capacitance-sensitive region, while the metal trench 114B can still be made thick to achieve a small resistance in the resistance-sensitive region. As a result, resistance-capacitance delays can be optimized or effectively reduced respectively in the capacitance-sensitive region and the resistance-sensitive region that are disposed in the same interconnection layer. Particularly, such effects may be more pronounced in lower interconnection layers (e.g., so-called metal 1 layer, metal 2 layer, metal 3 layer, etc.), which usually have higher densities of metal lines. Moreover, since they are made thicker, the metal lines in the resistance-sensitive region may have a smaller current density and thus larger electromigration window, thereby being able to withstand higher electric power. In accordance with some embodiments, the difference between the metal trenches 114A and the metal trench 114B in thickness may range from about 20 angstroms to about 500 angstroms to achieve the above mentioned effects. In more detail, the top surfaces of the metal trenches 114A are coplanar with the top surface of the metal trench 114B, and are positioned at the same height as the top surface of the metal trench 114B relative to the top surface of the substrate 100; the bottom surfaces of the metal trenches 114A (or the top surfaces of the metal vias 112A) are higher in position than the bottom surface of the metal trench 114B (or the top surface of the metal via 112B) relative to the top surface of the substrate 100; and the bottom surfaces of the metal vias 112A are coplanar with the bottom surface of the metal via 112B. In this embodiment, since the metal vias 112A, 112B and the metal trenches 114A, 114B are formed in the same layer (i.e., the second interconnection layer, or the layer of the second dielectric 110), the interconnection features 200A, 200B have substantially the same height (namely, a distance between the top surface of a single metal trench 114A and the bottom surface of the corresponding metal via 112A (or a top surface of the corresponding metal trench 104A) is equal to a distance between the top surface of the metal trench 114B and the bottom surface of the corresponding metal via 112B (or a top surface of the metal trench 104B)). In other words, a sum of thicknesses D₁, H₁ respectively of the metal via 112A and the metal trench 114A of a single interconnection feature 200A is substantially equal to a sum of thicknesses D₂, H₂ respectively of the metal via 112B and the metal trench 114B of the interconnection feature 200B (i.e., D₁+H₁=D₂+H₂), and thus the thickness D₁ of the metal via 112A is greater than the thickness D₂ of the metal via 112B.

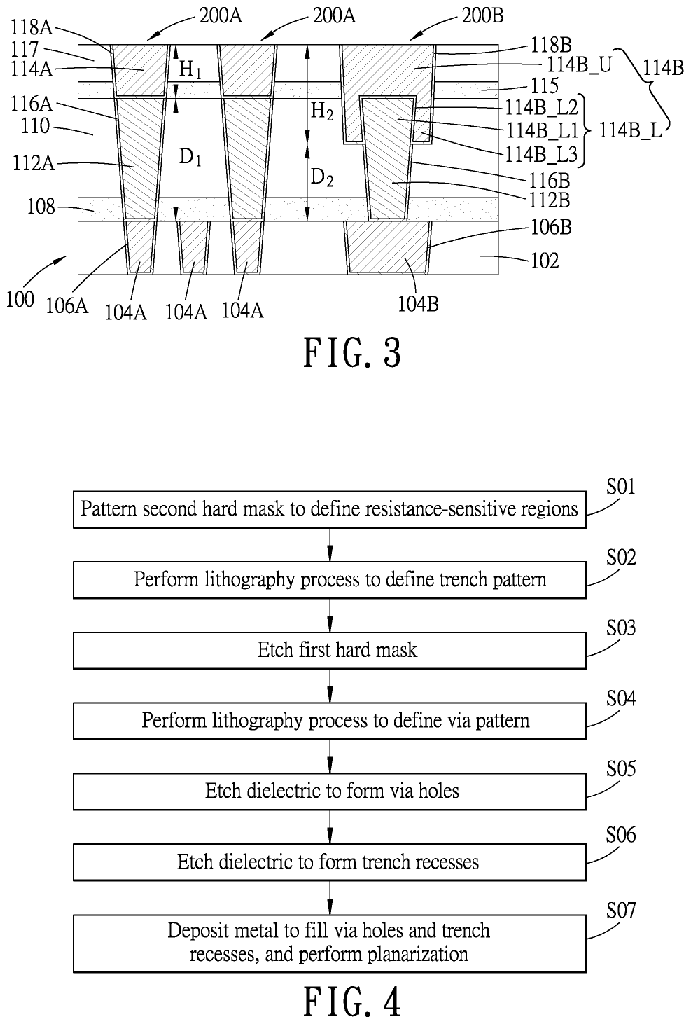

FIG. 3 illustrates a sectional view of an interconnection structure in accordance with a third embodiment, where the interconnection structure is fabricated using a single damascene process. Similar to the second embodiment, the thickness H₁ of the metal trenches 114A that are formed in the capacitance-sensitive region is smaller than the thickness H₂ of the metal trench 114B that is formed in the resistance-sensitive region in the third embodiment. In the third embodiment, another etch stop layer 115 (referred to as a second etch stop layer hereinafter, while the etch stop layer 108 will be referred to as a first etch stop layer) is formed over the second dielectric 110, and a third dielectric 117 is disposed over the second etch stop layer 115. In accordance with some embodiments, the second etch stop layer 115 may include either the same material as or a different material from the first etch stop layer 108, and the third dielectric 117 may include either the same material as or a different material from the first dielectric 102 and/or the second dielectric 110. The metal vias 112A, 112B are formed in the second dielectric 110 and penetrate the first etch stop layer 108. The metal trenches 114A are formed in the third dielectric 117 and penetrate the second etch stop layer 115 to connect with the metal vias 112A. The metal trench 114B extends through the second etch stop layer 115, and has a first portion 114B_U (e.g., an upper portion in FIG. 3) that is disposed in the third dielectric 117, and a second portion 114B_L (e.g., a lower portion in FIG. 3) that is disposed in the second dielectric 110. For each interconnection feature 200A, a barrier film 116A is conformally disposed on a sidewall and a bottom of the metal via 112A, and a barrier film 118A is conformally disposed on a sidewall and a bottom of the metal trench 114A. For the interconnection feature 200B, a barrier film 116B is conformally disposed on a sidewall and a bottom of the metal via 112B, and a barrier film 118B is conformally disposed on a sidewall and a part of a bottom of the metal trench 114B. In the illustrative embodiment, a part 114B_L1 of the metal trench 114B can be considered an extension of the metal via 112B that extends through a bottom surface of the metal trench 114B and that has a top surface coplanar with top surfaces of the metal vias 112A; and a part of the barrier film 118B is formed within the metal trench 114B, is conformally disposed on a sidewall and a top of the extension of the metal via 112B, and is considered an inner part 114B_L2 of the metal trench 114B. As a result, the second portion 114B_L of the metal trench 114B, which is disposed in the second dielectric 110, has a first sub-portion 114B_L1 (e.g., the extension of the metal via 112B), a second sub-portion 114B_L2 (e.g., the part of the barrier film 118B that is formed within the metal trench 114B and considered an inner part of the metal trench 114B) that is conformally disposed on the first sub-portion, and a third sub-portion 114B_L3 (e.g., an outer part of the lower portion of the metal trench 114B in FIG. 3) that cooperates with the first sub-portion 114B_L1 to sandwich the second sub-portion 114B_L2 therebetween. The second sub-portion 114B_L2 is a part of the barrier film 118B, and is thus different from the first sub-portion 114B_L1 and the third sub-portion 114B_L3 in terms of materials. In the illustrative embodiment, the third sub-portion 114B_L3 of the second portion 114B_L of the metal trench 114B is made to be wider than the first sub-portion 114B_L1 of the second portion 114B_L of the metal trench 114B, and the third sub-portion 114B_L3 may surround the first and second sub-portions 114B_L1, 114B_L2, but this disclosure is not limited to this respect. In accordance with some embodiments, the third sub-portion 114B_L3 of the second portion 114B_L of the metal trench 114B may be made to be narrower than the first sub-portion 114B_L1 of the second portion 114B_L of the metal trench 114B, and the third sub-portion 114B_L3 may have two extensions that are disposed at two opposite sides of the first and second sub-portions 114B_L1, 114B_L2.

To describe the third embodiment from another point of view, the metal via 112A and the barrier film 116A may be collectively deemed as a first metal via feature, the metal trench 114A and the barrier film 118A may be collectively deemed as a first metal trench feature, the metal via 112B, the extension of the metal via 112B (i.e., the first sub-portion 114B_L1 of the second portion 114B_L of the metal trench 114B) and the barrier film 116B may be collectively deemed as a second metal via feature, and the remaining portion of the metal trench 114B (i.e., the portion other than the extension of the metal via 112B, which is composed of the first portion 114B_U of the metal trench 114B and the third sub-portion 114B_L3 of the second portion 114B_L of the metal trench 114B) and the barrier film 118B may be collectively deemed as a second metal trench feature, where the metal via 112A serves as a via body of the first metal via feature, the metal trench 114A serves as a trench body of the first metal trench feature, the metal via 112B and its extension collectively serve as a via body of the second metal via feature, and the remaining portion of the metal trench 114B serves as a trench body of the second metal trench feature. In such a point of view, the barrier film 118A separates the trench body of the first metal trench feature from the via body of the first metal via feature. The second metal via feature extends into the second metal trench feature, where one portion of the via body of the second metal via feature (i.e., the metal via 112B) is disposed outside the second metal trench feature, and the other portion of the via body of the second metal via feature (i.e., the extension of the metal via 112B) is surrounded by the trench body of the second metal trench feature. The barrier film 118B separates the trench body of the second metal trench feature from the via body of the second metal via feature, where the barrier film 118B has a portion that is disposed between the trench body of the second metal trench feature and a top surface of the extension of the metal via 112B, and between the trench body of the second metal trench feature and a sidewall of the extension of the metal via 112B.

FIG. 4 is a flow chart illustrating some exemplary steps of a method for fabricating the interconnection structure in accordance with the second embodiment.

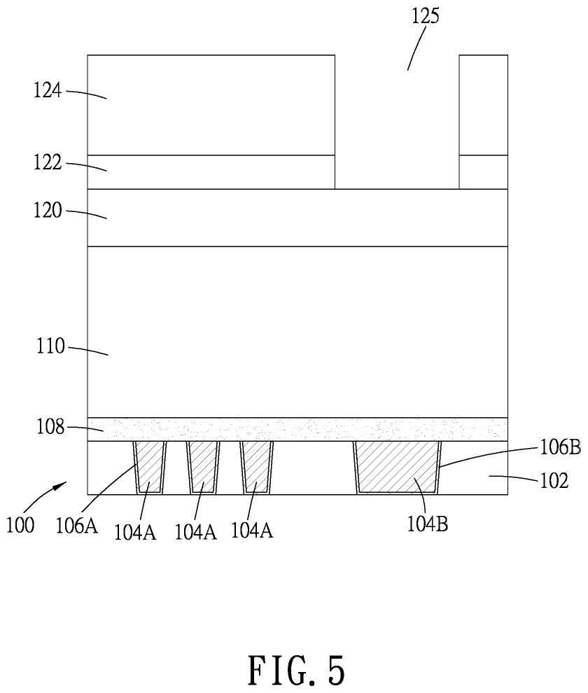

Referring to FIGS. 4 and 5, the etch stop layer 108, the second dielectric 110, a first hard mask layer 120, a second hard mask layer 122, and a first photoresist film 124 are formed on top of the substrate 100 in the given order from bottom to top. The second hard mask layer 122 is patterned to form a region-defining recess 125 that defines the resistance-sensitive region using a lithography process with the first photoresist film 124 serving as an etching mask (step S01). In accordance with some embodiments, the first dielectric 102 and the second dielectric 110 may be formed using, for example, physical vapor deposition (PVD), chemical vapor deposition (CVD), other suitable techniques, or any combination thereof. In accordance with some embodiments, the metal trenches 104A, 104B may be formed using, for example, PVD, CVD, electrochemical plating (ECP), atomic layer deposition (ALD), other suitable techniques, or any combination thereof. In accordance with some embodiments, the barrier films 106A, 106B may be formed using, for example, ALD, other suitable techniques, or any combination thereof. In accordance with some embodiments, the etch stop layer 108 may be formed using, for example, PVD, CVD, ALD, plasma-enhanced CVD (PECVD), other suitable techniques, or any combination thereof. In accordance with some embodiments, each of the first hard mask layer 120 and the second hard mask layer 122 may include, for example, Si-based or metal-based (e.g., W, Ti, Ta, or other suitable metal elements) nitride, Si-based or metal-based carbide, other suitable materials, or any combination thereof, and may be formed using, for example, PVD, CVD, ALD, PECVD, other suitable techniques, or any combination thereof. In accordance with some embodiments, the first hard mask layer 120 and the second hard mask layer 122 may include either the same material or different materials, and each may have a thickness in a range from about 50 angstroms to about 1000 angstroms. The etching of the second hard mask layer 122 may be performed using, for example, dry etching, wet etching, other suitable etching techniques, or any combination thereof. In accordance with some embodiments, the first photoresist film 124 may be of either a single layer structure or a multilayer structure (e.g., including a bottom anti-reflective coating (BARC) layer and a photoresist layer, or including a bottom layer, a middle layer and a photoresist layer, or being other types of multilayer structures).

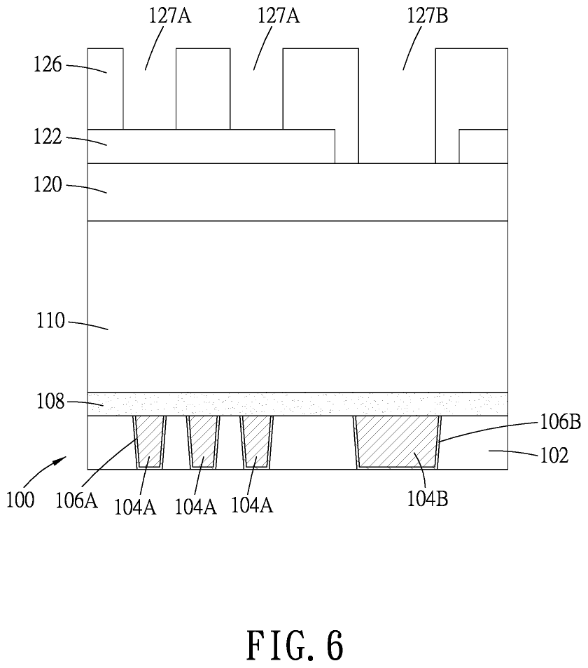

Referring to FIGS. 4 and 6, a lithography process is performed to define a trench pattern (step S02). In detail, the first photoresist film 124 (see FIG. 5) is removed, then a second photoresist film 126 is coated on the second hard mask layer 122 and a part of the first hard mask layer 120 that is revealed from the region-defining recess 125 (see FIG. 5), and the second photoresist film 126 is patterned by exposure and development processes to form the trench pattern therein. In the illustrative embodiment, the trench pattern includes multiple first photoresist recesses 127A that are disposed in the capacitance-sensitive region, and a second photoresist recess 127B that is disposed in the resistance-sensitive region, where the second photoresist recess 127B is narrower than the region-defining recess 125. In accordance with some embodiments, the second photoresist film 126 may be of either a single layer structure or a multilayer structure (e.g., including a BARC layer and a photoresist layer, or including a bottom layer, a middle layer and a photoresist layer, or being other types of multilayer structures). In the illustrative embodiment, the second photoresist recess 127B is wider than each of the first photoresist recesses 127A, so as to result in a wider metal trench that has a smaller resistance in the resistance-sensitive region.

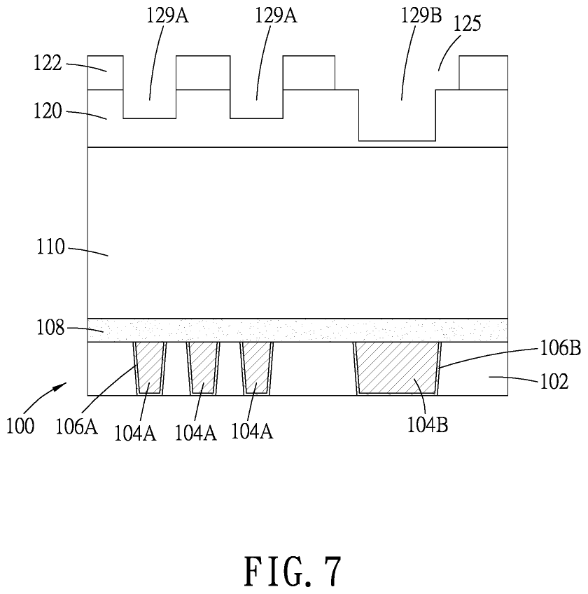

Referring to FIGS. 4 and 7, the second hard mask layer 122 and the first hard mask layer 120 are etched (step S03) with the patterned second photoresist film 126 (see FIG. 6) serving as an etching mask, so as to form multiple first hard mask recesses 129A and a second hard mask recess 129B in the first hard mask layer 120, where the first hard mask recesses 129A correspond in position to the first photoresist recesses 127A (see FIG. 6), and the second hard mask recess 129B corresponds in position to the second photoresist recess 127B (see FIG. 6) and is narrower than the region-defining recess 125 formed in the second hard mask layer 122. The etching of the second hard mask layer 122 and the first hard mask layer 120 may be performed using, for example, dry etching, wet etching, other suitable etching techniques, or any combination thereof. Since the second hard mask layer 122 has been etched in step S01, the second hard mask recess 129B is etched to be deeper than the first hard mask recesses 129A, which means that the first hard mask layer 120 is thinner under the second hard mask recess 129B than under the first hard mask recesses 129A. In accordance with some embodiments, the second dielectric 110 may be revealed in the second hard mask recess 129B, namely, the first hard mask layer 120 is completely removed at the position of the second hard mask recess 129B).

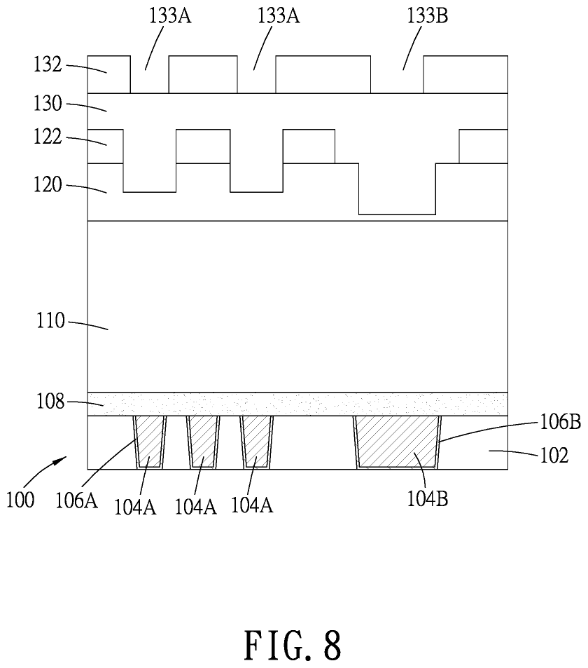

Referring to FIGS. 4 and 8, a lithography process is performed to define a via pattern (step S04). In detail, a BARC layer 130 and a third photoresist film 132 are formed over the first hard mask layer 120 and the second hard mask layer 122, and the third photoresist film 132 is patterned by exposure and development processes to form the via pattern therein. In the illustrative embodiment, the via pattern includes multiple third photoresist recesses 133A that correspond in position to and are narrower than the first hard mask recesses 129A (see FIG. 7), and a fourth photoresist recess 133B that corresponds in position to and is narrower than the second hard mask recess 129B. In accordance with some embodiments, the BARC layer 130 may be either of a single-layer structure or a multilayer structure.

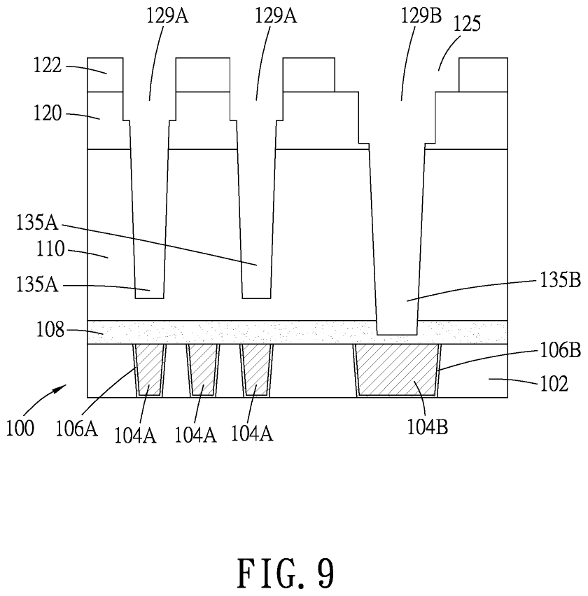

Referring to FIGS. 4, 8 and 9, the BARC layer 130 is patterned with the third photoresist film 132 serving as an etching mask to transfer the via pattern to the BARC layer 130, and the first hard mask layer 120 and the second dielectric 110 are etched (step S05) with the patterned BARC layer 130 serving as an etching mask, thereby forming in the second dielectric 110 a plurality of first via holes 135A that correspond in position to the third photoresist recesses 133A, and a second via hole 135B that corresponds in position to the fourth photoresist recess 133B and that is deeper than the first via holes 135A. Then, the BARC layer 130 may be removed by ashing. In accordance with some embodiments, the etching of the second dielectric 110 may be performed using, for example, anisotropic etching, other suitable techniques, or any combination thereof. When the third photoresist film 132 and the BARC layer 130 are completely removed during the etching of the second dielectric 110, the etching of the second dielectric 110 continues with the first hard mask layer 120 serving as an etching mask, so as to transfer the trench pattern into the second dielectric 110. As shown in FIG. 10, the second dielectric 110 is thus etched to form therein a plurality of first trench recesses 137A that correspond in position to the first hard mask recesses 129A, and a second trench recess 137B that corresponds in position to the second hard mask recess 129B (step S06). Since the first hard mask layer 120 is thinner under the second hard mask recess 129B than under the first hard mask recesses 129A before the etching (see FIG. 9), the resultant second trench recess 137B would be deeper than the first trench recesses 137A. During the formation of the trench recesses 137A and 137B, the via holes 135A, 135B become deeper as well. Because of the previous process steps, the via hole 135B would reach the metal trench 104B before the via holes 135A reach the corresponding metal trenches 104A, so the etching will continue when the via hole 135B has reached the metal trench 104B. Since the metal trench 104B that is disposed in the resistance-sensitive region is usually wide, which may prevent the via hole 135B from, even if only partially, falling outside a range of the metal trench 104B because of a minor misalignment between the via hole 135B and the metal trench 104B, the continuous etching would not undesirably damage the second dielectric 110 nearby the metal trench 104B and cause defects accordingly (e.g., so called tiger tooth defects).

After the trench recesses 137A, 137B are formed in step S06, a barrier layer is conformally deposited in the trench recesses 137A, 137B, and a metal layer is deposited to fill up the via holes 135A, 135B and the trench recesses 137A, 137B (step S07), followed by performing a planarization process (e.g., chemical-mechanical planarization, abbreviated as CMP) to remove excessive part of the metal layer, so as to form the interconnection structure as shown in FIG. 2, where the barrier films 116A, 116B are conformally disposed on sidewalls of the trench recesses 137A, 137B and the via holes 135A, 135B, the metal vias 112A, 112B are formed in the via holes 135A, 135B, and the metal trenches 114A, 114B are formed in the trench recesses 137A, 137B. In accordance with some embodiments, the barrier layer may be formed using, for example, ALD, other suitable techniques, or any combination thereof. In accordance with some embodiments, the metal layer may be formed using, for example, PVD, CVD, ECP, ALD, other suitable techniques, or any combination thereof.

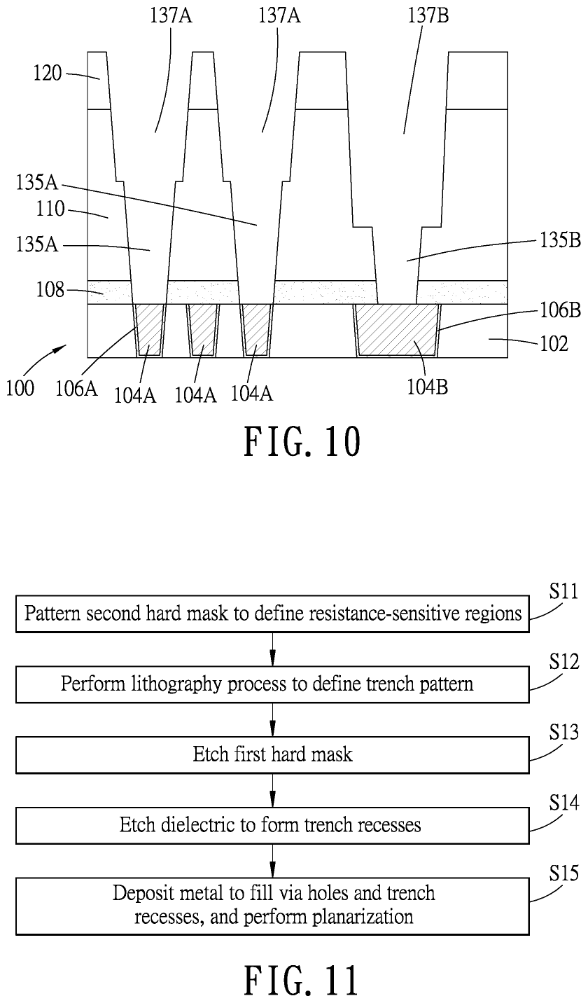

FIG. 11 is a flow chart illustrating some exemplary steps of a method for fabricating the interconnection structure in accordance with the third embodiment.

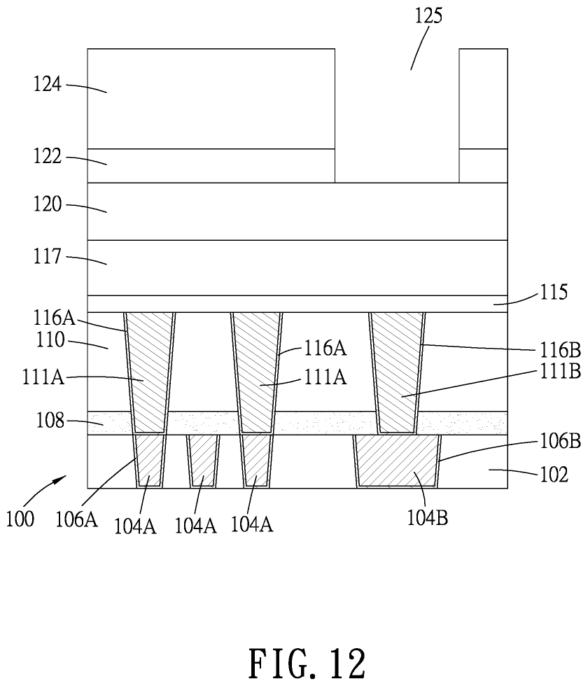

Referring to FIGS. 11 and 12, the first etch stop layer 108, the second dielectric 110, the second etch stop layer 115, the third dielectric 117, a first hard mask layer 120, a second hard mask layer 122, and a first photoresist film 124 are formed on top of the substrate 100 in the given order from bottom to top, where the second dielectric 110 has metal via features formed therein. In the illustrative embodiment, the metal via features include multiple first metal via features that are disposed in the capacitance-sensitive region, and a second metal via feature that is disposed in the resistance-sensitive region. Each first metal via feature includes a metal bulk 111A, and a barrier film 116A disposed between the metal bulk 111A and the second dielectric 110. The second metal via feature includes a metal bulk 111B, and a barrier film 116B disposed between the metal bulk 111B and the second dielectric 110. The metal via features may be formed using a damascene process, and have coplanar top surfaces that are at the same height relative to the top surface of the substrate 100. The second hard mask layer 122 is patterned to form a region-defining recess 125 that defines the resistance-sensitive region using a lithography process with the first photoresist film 124 serving as an etching mask (step S11).

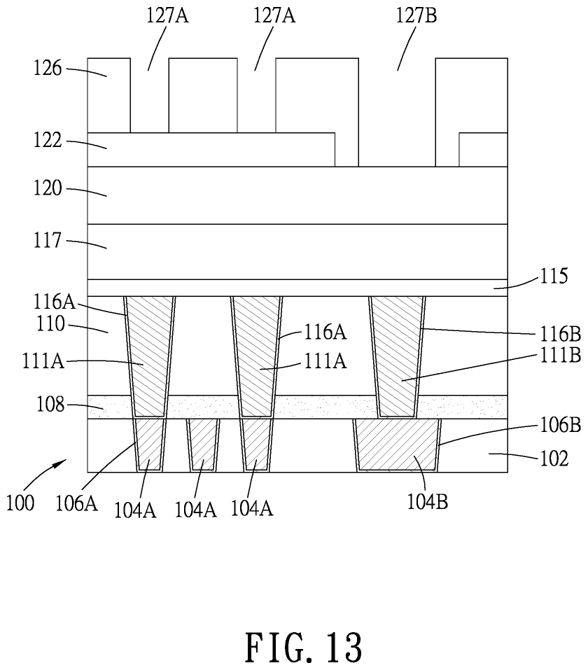

Referring to FIGS. 11 and 13, a lithography process is performed to define a trench pattern (step S12). In detail, the first photoresist film 124 (see FIG. 12) is removed, then a second photoresist film 126 is coated on the second hard mask layer 122 and a part of the first hard mask layer 120 that is revealed from the region-defining recess 125 (see FIG. 12), and the second photoresist film 126 is patterned by exposure and development processes to form the trench pattern therein. In the illustrative embodiment, the trench pattern includes multiple first photoresist recesses 127A that are disposed in the capacitance-sensitive region, and a second photoresist recess 127B that is disposed in the resistance-sensitive region, where the second photoresist recess 127B is narrower than the region-defining recess 125. In the illustrative embodiment, the second photoresist recess 127B is wider than the first photoresist recesses 127A, so as to result in a wider metal trench that has a smaller resistance in the resistance-sensitive region.

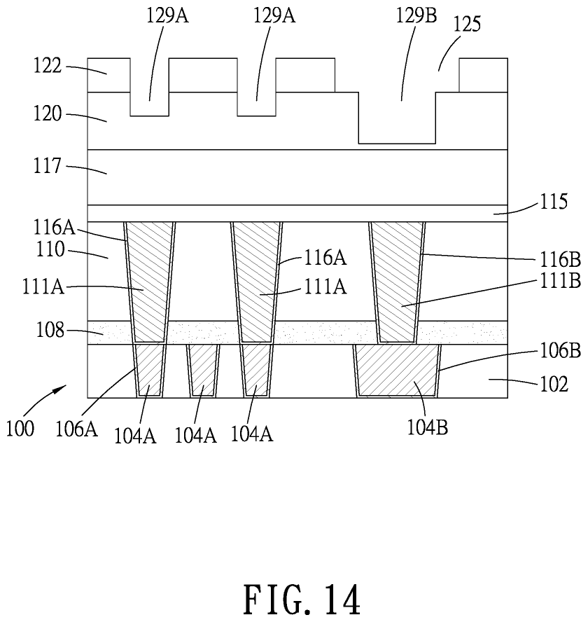

Referring to FIGS. 11 and 14, the second hard mask layer 122 and the first hard mask layer 120 are etched (step S13) with the patterned second photoresist film 126 (see FIG. 13) serving as an etching mask, so as to form multiple first hard mask recesses 129A and a second hard mask recess 129B in the first hard mask layer 120, where the first hard mask recesses 129A correspond in position to the first photoresist recesses 127A (see FIG. 13), and the second hard mask recess 129B corresponds in position to the second photoresist recess 127B (see FIG. 13) and is narrower than the region-defining recess 125 formed in the second hard mask layer 122. Since the second hard mask layer 122 has been etched in step S11, the second hard mask recess 129B is etched to be deeper than the first hard mask recesses 129A, which means that the first hard mask layer 120 is thinner under the second hard mask recess 129B than under the first hard mask recesses 129A. In accordance with some embodiments, the third dielectric 117 may be revealed in the second hard mask recess 129B, namely, the first hard mask layer 120 is completely removed at the position of the second hard mask recess 129B.

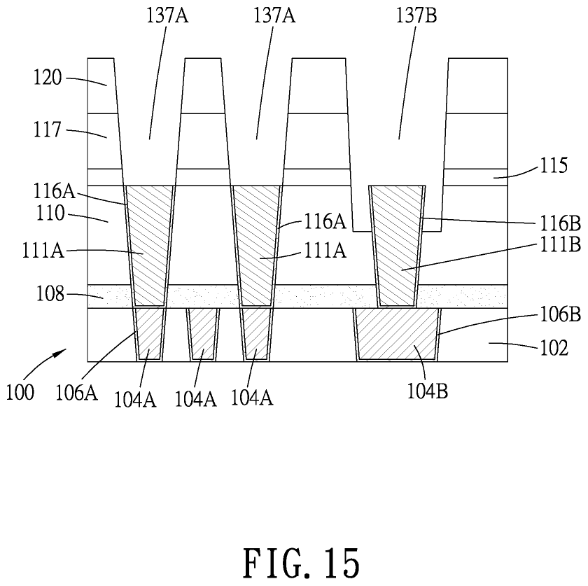

Referring to FIGS. 11 and 15, the third dielectric 117 and the second etch stop layer 115 are etched with the patterned first hard mask layer 120 serving as an etching mask, so as to form first trench recesses 137A and a second trench recess 137B (step S14) that respectively correspond in position to the first hard mask recesses 129A and the second hard mask recesses 129B (see FIG. 14), where top surfaces of the metal bulks 111A are revealed in the first trench recess 137A. Since the second hard mask recess 129B is deeper than the first hard mask recesses 129A before the etching (see FIG. 14), a progress of deepening the second trench recess 137B would be faster than a progress of deepening the first trench recesses 137A. When the etching progresses to the point where the top surfaces of the metal bulks 111A are revealed in the first trench recesses 137A, the second dielectric 110 at the position of the second trench recess 137B would have been etched to an extent where an upper portion of the second metal via feature is exposed in the second trench recess 137B, and a sidewall of the upper portion of the second metal via feature is spaced apart from a sidewall of the second trench recess 137B by air. In order to prevent the metal bulk 111B from etching damages, the etchant used in step S14 may be selected to have a high etching selectivity between the second dielectric 110 and the metal bulk 111B.

After the trench recesses 137A, 137B are formed in step S14, a barrier layer is conformally deposited in the trench recesses 137A, 137B, and a metal layer is deposited to fill up the trench recesses 137A, 137B (step S15), followed by performing a planarization process (e.g., CMP) to remove excessive portion of the metal layer, so as to form the interconnection structure as shown in FIG. 3, where each barrier film 118A is conformally disposed at a sidewall of a corresponding trench recess 137A, the barrier film 118B is conformally disposed at a sidewall of the trench recess 137B and the top surface and the sidewall of the upper portion of the second metal via feature, and the metal trenches 114A, 114B are formed in the trench recesses 137A, 137B. In the illustrative embodiment, the metal layer deposited in step S14 may be either the same as or different from the metal bulks 111A, 111B in terms of materials. Since the metal layer filled up the trench recess 137B, the resultant metal bulk in the trench recess 137B surrounds the upper portion of the second metal via feature, so the upper portion of the second metal via feature that extends into the trench recess 137B becomes a part of the metal trench 114B, and a part of the metal bulk 111B of the remaining portion of the second metal via feature serves as the metal via 112B. It is noted that, in FIG. 3, a portion of the barrier film 118B that is disposed within the metal trench 114B may be a combination of the barrier layer formed in step S15 and an upper portion of the barrier film 116B as shown in FIG. 15.

In accordance with some embodiments, an interconnection structure is provided to include a semiconductor substrate that is formed with a first metal trench and a second metal trench, a first metal via that is disposed over and connected to the first metal trench, a second metal via that is disposed over and connected to the second metal trench, a third metal trench that is disposed over and connected to the first metal via, and a fourth metal trench that is disposed over and connected to the second metal via. A thickness of the third metal trench is different from a thickness of the fourth metal trench.

In accordance with some embodiments, a top surface of the third metal trench is coplanar with a top surface of the fourth metal trench.

In accordance with some embodiments, a thickness of the first metal via is different from a thickness of the second metal via.

In accordance with some embodiments, a sum of the thicknesses of the first metal via and the third metal trench is equal to a sum of the thicknesses of the second metal via and the fourth metal trench.

In accordance with some embodiments, the semiconductor substrate includes a first dielectric layer in which the first metal trench and the second metal trench are formed. The interconnection structure further includes an etch stop layer disposed over the first dielectric layer, and a second dielectric layer disposed over the etch stop layer. The first metal via, the second metal via, the third metal trench and the fourth metal trench are disposed in the second dielectric layer.

In accordance with some embodiments, the semiconductor substrate includes a first dielectric layer in which the first metal trench and the second metal trench are formed. The interconnection structure further includes a first etch stop layer disposed over the first dielectric layer, a second dielectric layer disposed over the first etch stop layer, a second etch stop layer disposed over the second dielectric layer, and a third dielectric layer disposed over the second etch stop layer. The first metal via and the second metal via are disposed in the second dielectric layer. The third metal trench is disposed in the third dielectric layer. The fourth metal trench has a first portion that is disposed in the third dielectric layer, and a second portion that is disposed in the second dielectric layer.

In accordance with some embodiments, the second portion of the fourth metal trench has a first sub-portion, a second sub-portion that is conformally disposed on the first sub-portion, and a third sub-portion that cooperates with the first sub-portion to sandwich the second sub-portion therebetween. The second sub-portion is different from the first sub-portion and the third sub-portion in terms of materials.

In accordance with some embodiments, a top surface of the first sub-portion of the second portion of the fourth metal trench is coplanar with a top surface of the first metal via.

In accordance with some embodiments, the second metal trench is wider than the first metal trench, and the fourth metal trench is thicker than the third metal trench.

In accordance with some embodiments, an interconnection structure is provided to include a semiconductor substrate that is formed with a first metal trench and a second metal trench, a third metal trench that is disposed over the semiconductor substrate and that extends parallel to a top surface of the semiconductor substrate, a fourth metal trench that is disposed over the semiconductor substrate and that extends parallel to the top surface of the semiconductor substrate, a first metal via that extends from the first metal trench to the third metal trench, and a second metal via that extends from the second metal trench to the fourth metal trench. A distance between a top surface and a bottom surface of the third metal trench is different from a distance between a top surface and a bottom surface of the fourth metal trench.

In accordance with some embodiments, the top surfaces of the third metal trench and the fourth metal trench are at a same height relative to the top surface of the semiconductor substrate.

In accordance with some embodiments, a distance between the top surface of the third metal trench and a top surface of the first metal trench is equal to a distance between the top surface of the fourth metal trench and a top surface of the second metal trench.

In accordance with some embodiments, the distance between the top surface and the bottom surface of the fourth metal trench is greater than the distance between the top surface and the bottom surface of the third metal trench, and the second metal trench is wider than the first metal trench.

In accordance with some embodiments, an interconnection structure is provided to include a first interconnection layer that includes a first metal trench feature and a second metal trench feature, and a second interconnection layer that is disposed over the first interconnection layer, and that includes a first metal via feature, a second metal via feature, a third metal trench feature and a fourth metal trench feature. The first metal via feature connects the third metal trench feature to the first metal trench feature, and the second metal via feature connects the fourth metal trench feature to the second metal trench feature. A thickness of the third metal trench feature is different from a thickness of the fourth metal trench feature.

In accordance with some embodiments, a top surface of the third metal trench feature is coplanar with a top surface of the fourth metal trench feature.

In accordance with some embodiments, a distance between the top surface of the third metal trench feature and a top surface of the first metal trench feature is equal to the top surface of the fourth metal trench feature and a top surface of the second metal trench feature.

In accordance with some embodiments, the fourth metal trench feature is thicker than the third metal trench feature, and the second metal trench feature is wider than the first metal trench feature.

In accordance with some embodiments, each of the first metal via feature and the second metal via feature includes a via body, and a via barrier film that is different from the via body in terms of materials, and that is conformally disposed on a sidewall of the via body. Each of the third metal trench feature and the fourth metal trench feature includes a trench body, and a trench barrier film that is different from the trench body in terms of materials, and that is conformally disposed on a sidewall of the trench body. The via body of the first metal via feature and the trench body of the third metal trench feature are formed in one piece. The via body of the second metal via feature and the trench body of the fourth metal trench feature are formed in one piece.

In accordance with some embodiments, each of the first metal via feature and the second metal via feature includes a via body, and a via barrier film that is different from the via body in terms of materials, and that is conformally disposed on a sidewall of the via body. Each of the third metal trench feature and the fourth metal trench feature includes a trench body, and a trench barrier film that is different from the trench body in terms of materials, and that is conformally disposed on a sidewall of the trench body. The second metal via feature extends into the fourth metal via feature. The trench barrier film of the third metal trench feature separates the trench body of the third metal trench feature from the via body of the first metal via feature. The trench barrier film of the fourth metal trench feature cooperates with the via barrier film of the second metal via feature to separate the trench body of the fourth metal trench feature from the via body of the second metal via feature.

In accordance with some embodiments, one portion of the via body of the second metal via feature is disposed outside of the fourth metal trench feature, and another portion of the via body of the second metal via feature is disposed within the trench body of the fourth metal trench feature. A portion of the barrier film of the fourth metal trench feature is disposed between the trench body of the fourth metal trench feature and a top surface of said another portion of the via body of the second metal via feature, and between the trench body of the fourth metal trench feature and a sidewall of the other portion of the via body of the second metal via feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnection structure, comprising:
a semiconductor substrate that is formed with a first metal trench and a second metal trench;
a first metal via that is disposed over and connected to the first metal trench;
a second metal via that is disposed over and connected to the second metal trench;
a third metal trench that is disposed over and connected to the first metal via; and
a fourth metal trench that is disposed over and connected to the second metal via,
wherein a thickness of the third metal trench is different from a thickness of the fourth metal trench.

2. The interconnection structure according to claim 1, wherein a top surface of the third metal trench is coplanar with a top surface of the fourth metal trench.

3. The interconnection structure according to claim 1, wherein a thickness of the first metal via is different from a thickness of the second metal via.

4. The interconnection structure according to claim 3, wherein a sum of the thicknesses of the first metal via and the third metal trench is equal to a sum of the thicknesses of the second metal via and the fourth metal trench.

5. The interconnection structure according to claim 1, wherein the semiconductor substrate includes a first dielectric layer in which the first metal trench and the second metal trench are formed;
the interconnection structure further comprising an etch stop layer disposed over the first dielectric layer, and a second dielectric layer disposed over the etch stop layer,
wherein the first metal via, the second metal via, the third metal trench and the fourth metal trench are disposed in the second dielectric layer.

6. The interconnection structure according to claim 1, wherein the semiconductor substrate includes a first dielectric layer in which the first metal trench and the second metal trench are formed;
the interconnection structure further comprising a first etch stop layer disposed over the first dielectric layer, a second dielectric layer disposed over the first etch stop layer, a second etch stop layer disposed over the second dielectric layer, and a third dielectric layer disposed over the second etch stop layer;
wherein the first metal via and the second metal via are disposed in the second dielectric layer;
wherein the third metal trench is disposed in the third dielectric layer; and
wherein the fourth metal trench has a first portion that is disposed in the third dielectric layer, and a second portion that is disposed in the second dielectric layer.

7. The interconnection structure according to claim 6, wherein the second portion of the fourth metal trench has a first sub-portion, a second sub-portion that is conformally disposed on the first sub-portion, and a third sub-portion that cooperates with the first sub-portion to sandwich the second sub-portion therebetween; and
wherein the second sub-portion is different from the first sub-portion and the third sub-portion in terms of materials.

8. The interconnection structure according to claim 7, wherein a top surface of the first sub-portion of the second portion of the fourth metal trench is coplanar with a top surface of the first metal via.

9. The interconnection structure according to claim 1, wherein the second metal trench is wider than the first metal trench, and the fourth metal trench is thicker than the third metal trench.

10. An interconnection structure, comprising:
a semiconductor substrate that is formed with a first metal trench and a second metal trench;
a third metal trench that is disposed over the semiconductor substrate and that extends parallel to a top surface of the semiconductor substrate;
a fourth metal trench that is disposed over the semiconductor substrate and that extends parallel to the top surface of the semiconductor substrate;
a first metal via that extends from the first metal trench to the third metal trench; and
a second metal via that extends from the second metal trench to the fourth metal trench,
wherein a distance between a top surface and a bottom surface of the third metal trench is different from a distance between a top surface and a bottom surface of the fourth metal trench.

11. The interconnection structure according to claim 10, wherein the top surfaces of the third metal trench and the fourth metal trench are at a same height relative to the top surface of the semiconductor substrate.

12. The interconnection structure according to claim 11, wherein a distance between the top surface of the third metal trench and a top surface of the first metal trench is equal to a distance between the top surface of the fourth metal trench and a top surface of the second metal trench.

13. The interconnection structure according to claim 10, wherein the distance between the top surface and the bottom surface of the fourth metal trench is greater than the distance between the top surface and the bottom surface of the third metal trench, and the second metal trench is wider than the first metal trench.

14. An interconnection structure, comprising:
a first interconnection layer that includes a first metal trench feature and a second metal trench feature; and
a second interconnection layer that is disposed over the first interconnection layer, and that includes a first metal via feature, a second metal via feature, a third metal trench feature and a fourth metal trench feature;
wherein the first metal via feature connects the third metal trench feature to the first metal trench feature, and the second metal via feature connects the fourth metal trench feature to the second metal trench feature; and
wherein a thickness of the third metal trench feature is different from a thickness of the fourth metal trench feature.

15. The interconnection structure according to claim 14, wherein a top surface of the third metal trench feature is coplanar with a top surface of the fourth metal trench feature.

16. The interconnection structure according to claim 15, wherein a distance between the top surface of the third metal trench feature and a top surface of the first metal trench feature is equal to the top surface of the fourth metal trench feature and a top surface of the second metal trench feature.

17. The interconnection structure according to claim 14, wherein the fourth metal trench feature is thicker than the third metal trench feature, and the second metal trench feature is wider than the first metal trench feature.

18. The interconnection structure according to claim 14, wherein each of the first metal via feature and the second metal via feature includes a via body, and a via barrier film that is different from the via body in terms of materials, and that is conformally disposed on a sidewall of the via body;
wherein each of the third metal trench feature and the fourth metal trench feature includes a trench body, and a trench barrier film that is different from the trench body in terms of materials, and that is conformally disposed on a sidewall of the trench body;
wherein the via body of the first metal via feature and the trench body of the third metal trench feature are formed in one piece; and
wherein the via body of the second metal via feature and the trench body of the fourth metal trench feature are formed in one piece.

19. The interconnection structure according to claim 14, wherein each of the first metal via feature and the second metal via feature includes a via body, and a via barrier film that is different from the via body in terms of materials, and that is conformally disposed on a sidewall of the via body;
wherein each of the third metal trench feature and the fourth metal trench feature includes a trench body, and a trench barrier film that is different from the trench body in terms of materials, and that is conformally disposed on a sidewall of the trench body;
wherein the second metal via feature extends into the fourth metal via feature;
wherein the trench barrier film of the third metal trench feature separates the trench body of the third metal trench feature from the via body of the first metal via feature; and
wherein the trench barrier film of the fourth metal trench feature cooperates with the via barrier film of the second metal via feature to separate the trench body of the fourth metal trench feature from the via body of the second metal via feature.

20. The interconnection structure according to claim 19, wherein one portion of the via body of the second metal via feature is disposed outside of the fourth metal trench feature, and another portion of the via body of the second metal via feature is disposed within the trench body of the fourth metal trench feature; and
wherein a portion of the barrier film of the fourth metal trench feature is disposed between the trench body of the fourth metal trench feature and a top surface of said another portion of the via body of the second metal via feature, and between the trench body of the fourth metal trench feature and a sidewall of the other portion of the via body of the second metal via feature.
